(19) United States
(12) Patent Application Publication
(10) Pub. No.: US 2008/0061434 A1
(43) Pub. Date: Mar. 13, 2008

(54) SUBSTRATE FOR SEMICONDUCTOR PACKAGE AND METHOD OF MANUFACTURING THE SAME

(75) Inventors: Ky-Hyun JUNG, Chungcheongnam-do (KR); Wha-Su SIN, Chungcheongnam-do (KR); Heui-Seog KIM, Chungcheongnam-do (KR); Sang-Jun KIM, Chungcheongnam-do (KR); Jun-Young KO, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/852,179

(22) Filed: Sep. 7, 2007

(30) Foreign Application Priority Data
Sep. 11, 2006 (KR) 2006-0087424

(51) Int. Cl. H01L 23/488; H01K 3/22

(52) U.S. Cl. 257/737; 29/848; 257/E23.023

(57) ABSTRACT

A substrate for a semiconductor package and a method of manufacturing the same are provided. More particularly, the substrate for the semiconductor package and the method for manufacturing the same include metal pieces, with some of the metal pieces having one end embedded within an insulating layer for insulating an external connection electrode of the substrate and the other end embedded within a solder. The substrate for the semiconductor package has the effects of preventing or retarding a connection failure in a solder connection portion by blocking or retarding the propagation of a crack, and allowing a solder to be easily permeated under the metal pieces and formed at a desired position.

### CROSS-REFERENCE TO RELATED PATENT APPLICATION

This application claims priority under 35 U.S.C. §119 to Korean Patent Application No. 10-2006-0087424, filed on Sep. 11, 2006, in the Korean Intellectual Property Office, the disclosure of which is incorporated herein in its entirety by reference.

### BACKGROUND

1. Technical Field

The present invention relates to a substrate for a semiconductor package and a method of manufacturing the same, and more particularly, to a substrate for a semiconductor package and a method of manufacturing the same which prevents or retards a connection failure in a solder connection portion by blocking or retarding the progress of a crack occurring in the solder connection portion and which allows a solder to be easily permeated under a metal piece and formed at a desired position.

2. Description of the Related Art

As electronic products development has become focused on miniaturization and mobile products, the demand for light, thin, short and small semiconductor devices has rapidly increased. Accordingly, the flip chip package and wafer level package are in the limelight as chip size packaging suitable for these applications. In the flip chip package, a semiconductor chip is directly packaged on a substrate. In the wafer level package, after an external electrode is formed at a wafer level, individual semiconductor chips are separated.

In these cases, a solder bump is generally used as an external connection terminal. When the solder bump experiences a change of temperature, a shearing stress is induced to the solder bump due to a difference of the coefficient of thermal expansion between a semiconductor chip and a substrate. Since a solder bump is made of metal material having mechanical strength, it is mostly capable of withstanding a shear force. However, when a temperature varies widely, a crack occurs on the connection interface of a solder bump or the surface of an external connection electrode.

Some research has been conducted to prevent the occurrence of a crack and some research has been conducted to block or retard the progress of a crack which has already occurred. A conventional technology has attempted to form a protrusion, which has a very great aspect ratio and a pillar shape, in a perpendicular direction of an electrode, on an external connection electrode. However, in the conventional technology, the mechanical strength is very weak and so the protrusion may often be broken during manufacturing. Moreover, since the protrusion's affinity with a solder bump is not good, it is difficult to form the solder bump at a desired position.

Consequently, to improve the reliability of a solder connection portion by blocking or retarding the progress of a crack occurring due to the change of temperature, a scheme is required for providing sufficient mechanical strength and for smoothly forming a solder bump.

### SUMMARY

The present invention provides a substrate for a semiconductor package which has sufficient mechanical strength and smoothly forms a solder bump, and is capable of blocking or retarding the progress of a crack.

The present invention also provides a method of manufacturing a substrate for a semiconductor package, which has sufficient mechanical strength and smoothly forms a solder bump, and is capable of blocking or retarding the progress of a crack.

According to an aspect of the present invention, there is provided a substrate for a semiconductor package, comprising: a board including external connection electrodes; an insulating layer insulating the external connection electrodes; solders formed on the external connection electrodes; and a plurality of metal pieces, wherein at least one of the metal pieces has one end embedded within the solder and the other end embedded within the insulating layer.

### BRIEF DESCRIPTION OF THE DRAWINGS

The above and other features and advantages of the present invention will become more apparent by describing in detail exemplary embodiments thereof with reference to the attached drawings in which:

FIG. 1 illustrates a substrate for a semiconductor package in accordance with an embodiment of the present invention;

FIGS. 2A and 2B are cross-sectional views illustrating a crack propagation in Part A of FIG. 1 in accordance with a conventional technology and the embodiment of the present invention, respectively;

FIGS. 3A and 3B are views illustrating a metal piece in accordance with some embodiments of the present invention;

FIGS. 4A and 4B are cross-sectional views illustrating the disposition of metal pieces in a substrate for a semiconductor package in accordance with some embodiments of the present invention;

FIG. 5 is a cross-sectional view illustrating a semiconductor package in accordance with some embodiments of the present invention; and

FIGS. 6A through 6F illustrate a method of manufacturing a substrate for a semiconductor package in accordance with some embodiments of the present invention.

### DETAILED DESCRIPTION

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Like numbers refer to like elements throughout the specification. Further, in the drawings, various elements and regions are schematically drawn. Therefore, this invention should not be limited by the relative size or space shown in the accompanying drawings.

An embodiment of the present invention provides a substrate for a semiconductor package, comprising: a board including an external connection electrode; an insulating layer for insulating the external connection electrodes from one another; a solder formed on the external connection electrode; and a plurality of metal pieces, wherein at least one of the metal pieces has one end embedded within the solder and the other end embedded within the insulating layer.

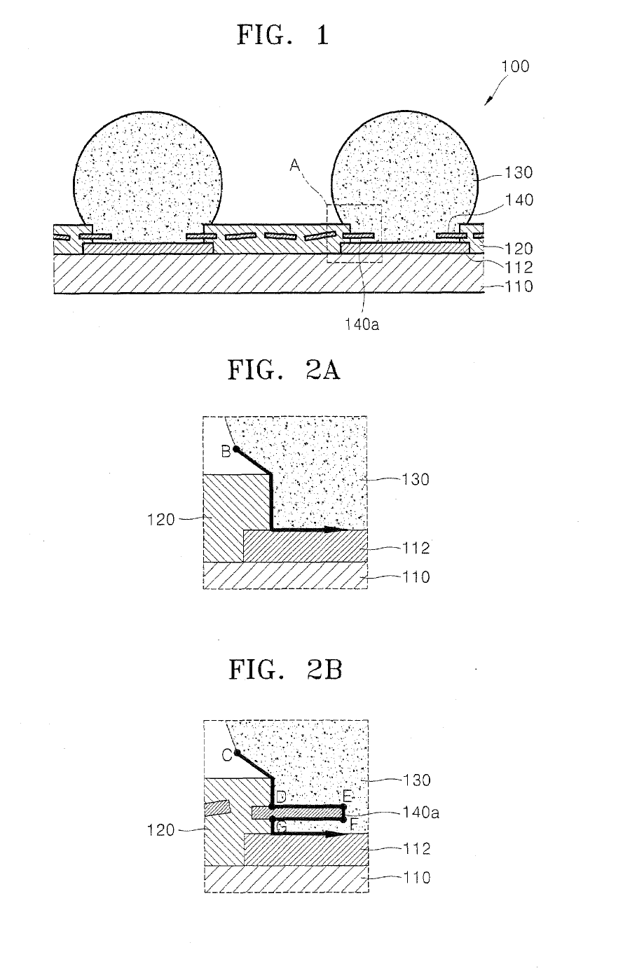

FIG. 1 is a cross-sectional view illustrating a substrate for a semiconductor package in accordance with an embodiment of the present invention.

As illustrated in FIG. 1, in a substrate 100 for a semiconductor package in accordance with an embodiment of the present invention, an insulating layer 120 is formed on a board 110 including external connection electrodes 112, and a solder 130 is formed on each external connection electrode 112. Metal pieces 140 are uniformly distributed within the insulating layer 120. Specifically, of the metal pieces 140, the metal piece 140a which is positioned close to the external connection electrode 112 has one end being embedded within the solder 130 and the other end being embedded within the insulating layer 120.

A crack at a connection portion of the solder 130 generally progresses along the connection interface of the solder 130 or the surface of the external connection electrode 112. The metal pieces 140 are used to decrease the chance of a device failure by increasing a path of the crack propagation. FIGS. 2A and 2B are views for explaining the difference in a growth characteristic of a crack by comparing a substrate with the metal pieces 140 to a substrate without the metal pieces 140. FIGS. 2A and 2B are cross-sectional views corresponding to portion A of FIG. 1, in the above-mentioned two substrates.

Referring to FIG. 2A, a crack starts from point B. The crack at the point B may originally occur at the point B or may occur at any other point and grow to reach the point B. The crack occurring at the point B or reaching the point B continuously grows along the interface of the solder. When contacting with the insulating layer 120, the crack continuously grows along the interface between the insulating layer 120 and the solder 130. When contacting with the external connection electrode 112, the crack continuously grows along the interface between the external connection electrode 112 and the solder 130.

Referring to FIG. 2B, a crack starts from point C. The point C corresponds to the point B of FIG. 2A. The crack starting from the point C continuously grows along the interface of the solder 130. When coming in contact with the insulating layer 120, the crack continuously grows along the interface between the insulating layer 120 and the solder 130. While growing, the crack meets the metal piece 140a. Then, since the crack cannot pass through the metal piece 140a, the crack can only grow around the metal piece 140a. Consequently, after the crack grows around a path DEFG of FIG. 2B, it keeps growing, along the interface of the solder as shown in FIG. 2A.

Upon comparing FIG. 2A of a conventional substrate with FIG. 2B of the substrate in accordance with the embodiment of the present invention, the crack in FIG. 2B needs a path as long as the path DEFG. That is, in accordance with the embodiment of the present invention, the crack progression is retarded along the path DEFG, resulting in junction failure being correspondingly retarded.

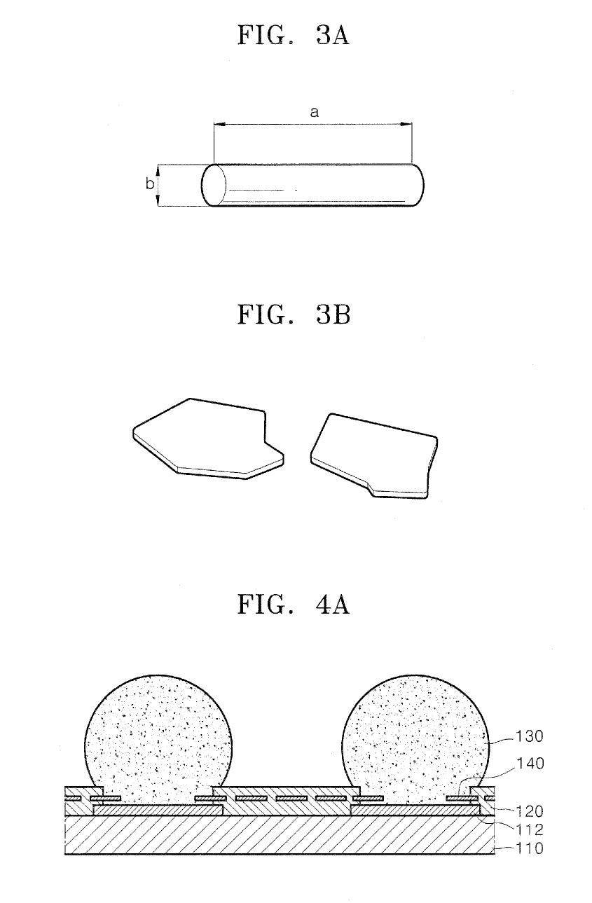

The metal pieces 140 may be in a pellet or platelet shape. FIGS. 3A and 3B illustrate examples of the shape of the metal pieces 140. FIG. 3A illustrates the metal pieces 140 in the pellet shape and FIG. 3B illustrates the metal pieces 140 in the platelet shape.

When the metal pieces 140 are each in the pellet shape, the length a of the metal pieces 140 may be about 10 to 50 μm and the diameter b of the metal pieces 140 may be about 5 to 30 μm

When the metal pieces 140 are each in the platelet shape, the thickness may be about 5 to 30 μm

Consideration of the uniform distribution of metal pieces 140, the prevention of shorts, and the mechanical strength, allows for variation of the dimensions of the metal pieces 140 within the ranges described above.

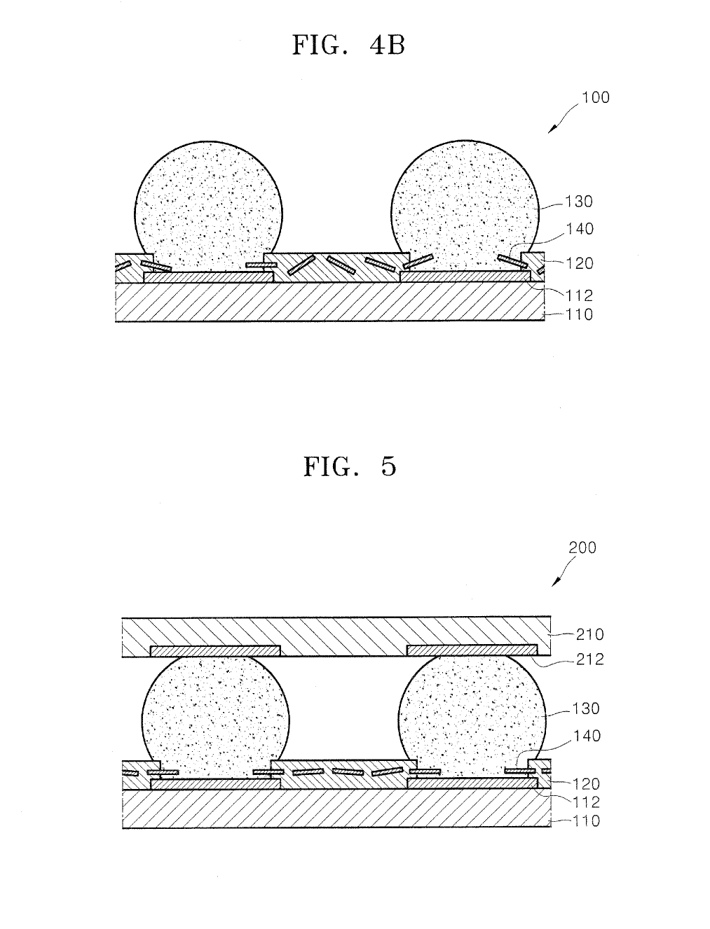

The orientation of the metal pieces 140 is not specifically limited. However, the metal pieces 140 may be disposed in a specific direction to be parallel to the direction of the board 110 as shown in FIG. 4A or they may be disposed at a random orientation as shown in FIG. 4B.

The material of the metal pieces 140 may be metal but is not limited specifically. For example, the material of the metal pieces 140 may be copper, nickel, or copper and nickel alloy. Specifically, gold may be plated on the cooper, nickel or copper and nickel alloy.

The insulating layer 120 may comprise one or more layers of insulating material. The insulating layer 120 may be composed of material which substantially insulates the current among the external connection electrodes 112 and/or it may be a photoresist layer. The photoresist may be a nonconductive polymer.

The external connection electrode 112 corresponds to a terminal of a circuit (not shown) formed on the board 110. The external connection electrode 112 may be formed of conductive material but it is not limited specifically. The end of the external connection electrode may be embedded within the insulating layer 120, as shown in FIG. 1.

The solder 130 may be formed using generally known material, and it is not specifically limited. A semiconductor chip (not shown) or semiconductor package (not shown) may be positioned on the solder 130, as described below with reference to FIG. 5.

A semiconductor package 200 in accordance with another embodiment of the present invention comprises the substrate 100 for a semiconductor package; and a semiconductor chip 210 mounted on the substrate 100 for a semiconductor package. Referring to FIG. 5, the semiconductor chip 210 is mounted on the substrate 100 for semiconductor package, and an external connection electrode 212 of the semiconductor chip 210 is jointed with the solder 130 so that they are electrically connected.

Below, a method of manufacturing a substrate for a semiconductor package will be described with reference to the corresponding drawings.

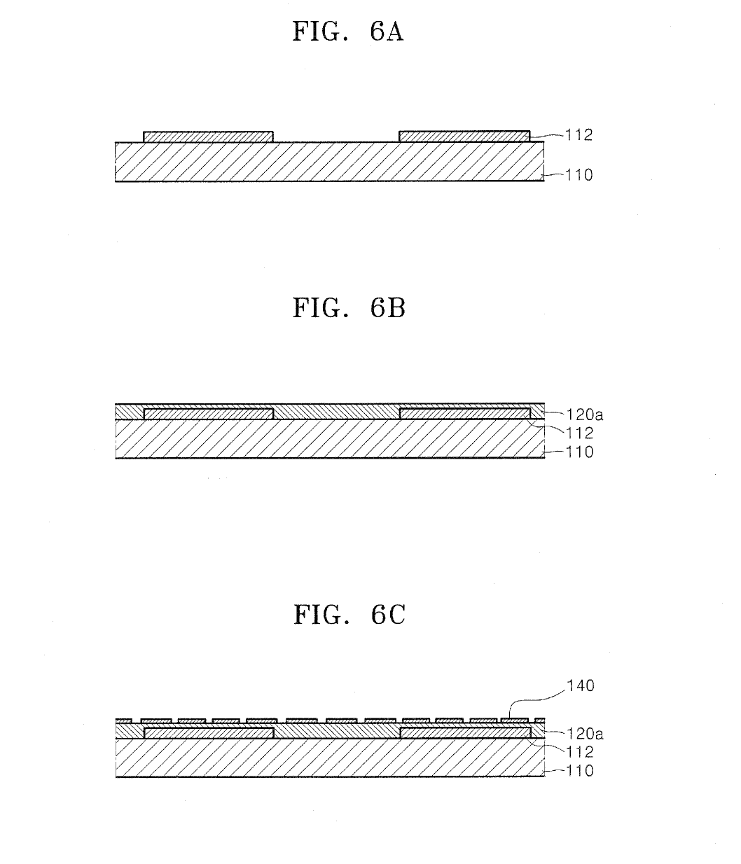

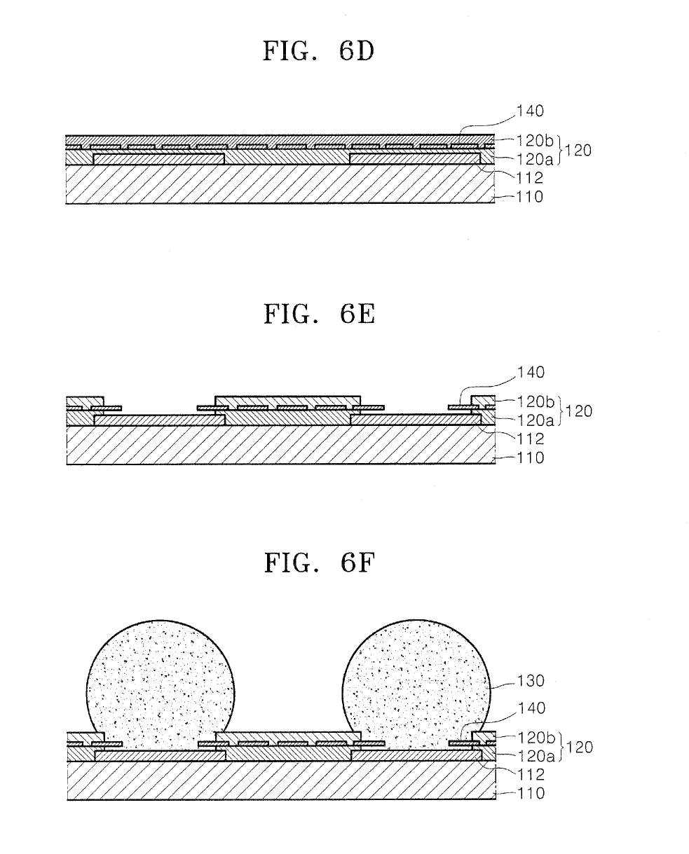

Referring to FIG. 6A, a circuit (not shown) is formed on a board 110, an external connection electrode 112 is formed to connect the circuit to an external circuit. The external connection electrode 112 may be formed by a known conventional patterning method, and a method of forming the external connection electrode is not specifically limited.

Referring to FIG. 6B, a first insulating layer 120a is formed on the whole surface of the board including the external connection electrode 112. The insulating layer 120a may be formed of a material which substantially insulates an electric current among the external connection electrodes 112. It is not specifically limited but it may be formed of, for example, photoresist or, specifically, nonconductive polymer photoresist. The first insulating layer 120a may be formed by a known method, and the method is not specifically limited.

Referring FIG. 6C, metal pieces 140 are uniformly distributed on the first insulating layer 120a. The metal pieces 140 may be formed in a random orientation or may be controlled to be formed in a regular orientation. Since the material or shape of the metal pieces 140 are the same as described above, no description thereof will be presented here.

Referring to FIG. 6D, a second insulating layer 120b is formed on the metal pieces 140 and the first insulating layer 120a. The second insulating layer 120b fixes the metal pieces 140 within the insulating layer 120. Like the first insulating layer 120a, the second insulating layer 120b is formed of material which substantially insulates an electric current. Although it is not specifically limited, the second insulating layer 120b may be formed of, for example, photoresist or, specifically, nonconductive polymer photoresist. The second insulating layer 120b may be formed by a known method, and the method is not specifically limited.

Referring to FIG. 6E, a portion of the first insulating layer 120a and the second insulating layer 120b on the external connection electrode 112 are removed from the resultant structure, thereby exposing the external connection electrode 112. The portion of the first insulating layer 120a and the second insulating layer 120b may be removed by a known general method, and it is not specifically limited. Specifically, when the insulating layer 120 is the photoresist, it may be removed by using photolithography. That is, after a mask is formed on the insulating layer 120 to be exposed to light, the exposed portion is developed and removed. The development may be performed using wet etching. According to some embodiments, portions of the first insulating layer 120a may be exposed to light before the metal pieces 140 are distributed on the first insulating layer 120a. Then, the metal pieces 140 and the second insulating layer 120b can be formed on the first insulating layer 120a. Next, corresponding portions of the second insulating layer 120b can be exposed to light and the exposed portions of both the first and second insulating layers 120a and 120b can be developed at the same time.

As illustrated in FIG. 6E, the first insulating layer 120a and the second insulating layer 120b may be removed so that the edge of the external connection electrode 112 is embedded within the insulating layer 120.

Referring to FIG. 6F, a solder 130 is formed on the external connection electrode 112 exposed by the removal of the portions of the first and second insulating layers 120a and 120b. The solder 130 may be formed by a known method, and it is not specifically limited. The solder 130 is capable of easily permeating to the concave portions under the metal pieces 140 by the surface characteristics of the metal pieces 140. In other words, the solder 130 easily wets to the surface of the metal pieces 140 and thereby fills the concave portions below the metal pieces 140.

The substrate for a semiconductor package in accordance with the present invention prevents or retards a junction failure of the solder connection portion from occurring by blocking or retarding the propagation of a crack, and allows the solder to easily permeate under the metal pieces and to be formed at a desired position. Further, one skilled in the art will appreciate that material pieces made of a material other than metal may be used within the spirit and scope of the present invention.

According to an aspect of the present invention, there is provided a substrate for a semiconductor package, comprising: a board including external connection electrodes; an insulating layer insulating the external connection electrodes; solders formed on the external connection electrodes; and a plurality of metal pieces, wherein at least one of the metal pieces has one end embedded within the solder and the other end embedded within the insulating layer.

The metal pieces may be in a pellet or platelet shape. When the metal pieces are each in the pellet shape, the metal pieces may be about 10 to about 50 μm in length and may be about 5 to about 30 μm in diameter. When the metal pieces are each in the platelet shape, the metal pieces may be about 5 to about 30 μm in thickness.

Specifically, the metal pieces may be disposed in a random orientation or in a specific orientation. The metal pieces may comprise one or more of copper, nickel, or a copper and nickel alloy, all of which may be gold plated.

The insulating layer may be a photoresist. Further, the external connection electrode may include an end being embedded in the insulating layer.

According to another aspect of the present invention, there is provided a method of manufacturing a substrate for semiconductor package, comprising: forming external connection electrodes on a board; forming a first insulating layer on a whole surface of the board; uniformly distributing metal pieces on the first insulating layer and forming a second insulating layer thereon; exposing the external connection electrodes, by removing a portion of the first and second insulating layers on the external connection electrodes; and forming solders on the exposed external connection electrodes.

The first and second insulating layers may be photoresist layers, and the first and second insulating layers may be removed by photolithography when exposing the external connection electrodes.

The metal pieces may be in a pellet or platelet shape. When the metal pieces are each in the pellet shape, the metal pieces may be about 10 to about 50 μm in length and may be about 5 to about 30 μm in diameter. When the metal pieces are each in the platelet shape, the metal pieces may be about 5 to about 30 μm in thickness.

Specifically, the metal pieces may be disposed in random orientation or in a specific orientation. The metal pieces may be composed of one or more of copper, nickel, or a copper and nickel alloy, all of which may be gold plated.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A substrate for a semiconductor package, comprising:
a board including external connection electrodes;
an insulating layer disposed on the external connection electrodes and the board;
solders formed on the external connection electrodes; and
a plurality of metal pieces, wherein at least one of the metal pieces has one end embedded within the solder and the other end embedded within the insulating layer.

2. The substrate of claim 1, wherein the metal pieces are each in a pellet shape.

3. The substrate of claim 2, wherein the metal pieces are each about 10 to about 50 μm in length.

4. The substrate of claim 2, wherein the metal pieces are each about 5 to 30 μm in diameter.

5. The substrate of claim 1, wherein the metal pieces are disposed in a random orientation.

6. The substrate of claim 1, wherein the metal pieces are disposed in a specific orientation.

7. The substrate of claim 1, wherein the metal pieces comprise one or more of copper, nickel, or a copper and nickel alloy, all of which may be gold plated.

8. The substrate of claim 1, wherein the insulating layer comprises photoresist.

9. The substrate of claim 1, wherein the metal pieces are each in a platelet shape.

10. The substrate of claim 9, wherein the metal pieces are each about 5 to about 30 μm in thickness.

11. The substrate of claim 1, wherein the external connection electrode includes an end embedded in the insulating layer.

12. A semiconductor package, comprising:
a substrate for a semiconductor package of claim 1; and
a semiconductor chip mounted on the substrate.

13. A method of manufacturing a substrate for a semiconductor package, comprising:
forming external connection electrodes on a board;
forming a first insulating layer on the board;
uniformly distributing metal pieces on the first insulating layer;
forming a second insulating layer on the first insulating layer and the metal pieces;
exposing the external connection electrodes, by removing a portion of the first and second insulating layers on the external connection electrodes; and
forming solders on the exposed external connection electrodes.

14. The method of claim 13, wherein the first and second insulating layers are photoresist layers, and the first and second insulating layers are removed by photolithography when exposing the external connection electrodes.

15. The method of claim 13, wherein the metal pieces are each in a pellet shape.

16. The method of claim 15, wherein the metal pieces are each about 10 to about 50 μm in length.

17. The method of claim 15, wherein the metal pieces are each about 5 to about 30 μm in diameter.

18. The method of claim 13, wherein the metal pieces are disposed in a random orientation.

19. The method of claim 13, wherein the metal pieces are disposed in a specific orientation.

20. The method of claim 13, wherein the metal pieces are each in a platelet shape.

21. The method of claim 20, wherein the metal pieces are each about 5 to about 30 μm in thickness.

22. A substrate for a semiconductor package, comprising:
a board including external connection electrodes;
an insulating layer overlying the external connection electrodes and the board;
conductive balls formed on the external connection electrodes; and
a plurality of material pieces, wherein at least one of the material pieces has one end embedded within at least one of the conductive balls.

23. The substrate of claim 22, wherein the other end of the at least one of the material pieces is embedded in the insulating layer.
